(19) United States
(12) Patent Application Publication
(10) Pub. No.: US 2024/0072030 A1
(43) Pub. Date: Feb. 29, 2024

(54) SEMICONDUCTOR POWER MODULE HAVING MORE EFFICIENT HEAT DISSIPATION AND IMPROVED SWITCHING BEHAVIOR

(71) Applicant: ZF Friedrichshafen AG, Friedrichshafen (DE)

(72) Inventors: Yuji Komatsu, Alkmaar (NL); Florian Wilhelmi, Friedrichshafen (DE)

(73) Assignee: ZF Friedrichshafen AG, Friedrichshafen (DE)

(21) Appl. No.: 18/455,956

(22) Filed: Aug. 25, 2023

(30) Foreign Application Priority Data
Aug. 26, 2022 (DE) 102022208838.7

(51) Int. Cl. H01L 25/18; H01L 23/538

(52) U.S. Cl. CPC H01L 25/18; H01L 23/5386; H01L 23/5383; H01L 24/48; H01L 2924/10253; H01L 2924/10272; H01L 2924/1033; H01L 2924/1067; H01L 2924/12032; H01L 2924/13055

(57) ABSTRACT

A semiconductor power module for an electrical axle drive in an electric vehicle and/or a hybrid vehicle includes a plurality of semiconductor switching elements for generating an output current on the basis of an input current provided by a voltage source by switching the semiconductor switching elements comprising a plurality of diodes which each have an anode and a cathode, a first leadframe, and a second leadframe having a plurality of conductor tracks for electrically connecting the semiconductor switching elements to form a half-bridge having a high side and a low side, wherein the first leadframe is assigned to the high side and the second leadframe is assigned to the low side, wherein electrical contact is made with the diodes between the first leadframe and the second leadframe so that the anode of the diodes faces a cooler mechanically connected and thermally coupled to the semiconductor power module.

### CROSS-REFERENCE TO RELATED APPLICATION

This application claims priority to German Application No. DE 10 2022 208 838.7, filed on Aug. 26, 2022, the entirety of which is hereby fully incorporated by reference herein.

### FIELD

The invention relates to a semiconductor power module for a power converter, in particular for an inverter, for supplying current to an electrical axle drive of an electric vehicle or a hybrid vehicle, a corresponding power converter, in particular an inverter, a corresponding electrical axle drive having such a power converter and a corresponding vehicle having such an electrical axle drive.

### BACKGROUND AND SUMMARY

Purely electric vehicles and hybrid vehicles which are driven completely or with assistance by one or more electric machines as powertrains are known from the prior art. In order to supply electrical energy to the electric machines of such electric vehicles or hybrid vehicles, the electric vehicles and hybrid vehicles comprise electrical energy stores, in particular rechargeable electric batteries. These batteries are in this case in the form of DC-voltage sources (DC sources), but the electric machines generally require an AC voltage. Therefore, power electronics having a so-called inverter are generally connected between a battery and an electric machine of an electric vehicle or a hybrid vehicle. In this case, the inverter converts a DC voltage into an AC voltage. In addition to purely electric vehicles, fuel cell vehicles are also known. Fuel cells convert chemical fuels such as hydrogen directly into electrical energy. The fuel cells act as rechargeable electric batteries if the electric motors are driven by electrical energy.

A power converter mentioned at the outset can also be a DC/DC converter or an AC/DC converter. The output voltage of batteries and fuel cells normally differs from the suitable voltage for the inverters. In this case, DC/DC converters are connected between the batteries or the fuel cells and convert the DC voltage of the batteries or the fuel cells into the corresponding voltage for inverters. When rechargeable batteries are charged by a line-coupled AC line, AC/DC converters are connected between the AC line and the batteries. An inverter also acts as an AC/DC converter when the motor is used as regenerative brake in order to charge the energy recovered in the rechargeable batteries.

Such power converters, in particular inverters, generally comprise semiconductor switching elements, which are typically formed from transistors, for example MOSFETs or IGBTs. In this case, it is known to configure the semiconductor switching elements as so-called half-bridges which have a high-side device (i.e. device on the side of the high potential) and a low-side device (i.e. device on the side of the low potential). This high-side or low-side device comprises one or more semiconductor switching elements connected in parallel which are controlled in a targeted manner during operation of the inverter in order to generate a plurality of phase currents of an AC current which are temporally offset with respect to one another from a direct current fed in on the input side of the half-bridges, wherein the phase currents are each variable over time and generally assume a sinusoidal waveform.

In the case of semiconductor power modules known from the prior art there is the problem that heat which is produced owing to high power losses in the semiconductor switching elements cannot be dissipated sufficiently effectively, in particular when semiconductor switching elements having a comparatively low thermal conductivity are used. The semiconductor switching elements are therefore subject to a risk of overheating, which can impair the functionality of the entire power converter.

One object of the invention is to provide a semiconductor power module for a power converter, in particular an inverter, in order to at least partially remedy the abovementioned disadvantages.

This object is achieved according to the invention by the semiconductor power module, the power converter, the electrical axle drive and the vehicle in accordance with the present disclosure. Advantageous configurations and developments of the invention can also be gleaned from the present disclosure.

The invention relates to a semiconductor power module for a power converter for operating an electrical axle drive in an electric vehicle and/or a hybrid vehicle. The power converter is preferably an inverter for converting a DC voltage into an AC voltage. Alternatively, the power converter can be in the form of a DC/DC converter for converting a DC input voltage into a DC output voltage that is different therefrom.

The semiconductor power module comprises a plurality of semiconductor switching elements for generating an output current on the basis of an input current provided by a voltage source by means of switching the semiconductor switching elements. In the case of an inverter, the input current is a direct current provided by a DC voltage source, wherein the output current is an alternating current having a plurality of phase currents. In the case of a DC/DC converter, the input current is a DC input current provided by a DC voltage source, wherein the output voltage is a DC voltage which is different than the DC input voltage, wherein the output current is a DC output current which is different than the DC input current and is preferably used for charging a vehicle battery, wherein the latter is supplied on the DC-output side.

The semiconductor switching elements comprise one or more diodes, which each have an anode and a cathode. Preferably, the semiconductor switching elements comprise one or more bipolar transistors, in particular IGBTs. The semiconductor material on which the bipolar transistors (in particular the IGBTs) are based is preferably silicon. Alternatively, a so-called wide bandgap semiconductor (WBS), for example silicon carbide or gallium nitride, can be used for the bipolar transistors (in particular the IGBTs). The one, individual or plurality of diodes are preferably in the form of Schottky diodes. The semiconductor material on which the diodes are based is preferably a gallium oxide compound or one of the abovementioned WBSs.

The semiconductor power module also comprises a first leadframe and a second leadframe having a plurality of conductor tracks for electrically connecting the semiconductor switching elements in order to form a half-bridge having a high side and a low side on the basis of the semiconductor switching elements. Advantageously, the semiconductor power module comprises a third leadframe. Preferably, the first leadframe is assigned to the high side and the second leadframe is assigned to the low side. Such an assignment of a leadframe to the high side or the low side means that a plurality of component parts, essential component parts of high side and low side, are arranged on the respective leadframe and/or are fastened thereto or control takes place via the gate terminal on the respective leadframe. For example, a leadframe is assigned to the high side or the low side when the transistors of the high side or the low side are arranged on this leadframe. In this way, a switch current can be conducted or blocked by the respective semiconductor switching elements. The first leadframe and/or the second leadframe and/or the third leadframe are provided by an upper metal layer of a multilayered substrate, in particular by two regions of the upper metal layer which are electrically insulated from one another or potentially isolated, wherein the substrate additionally comprises a lower metal layer and a layer of insulation located between the two metal layers. The substrate is, for example a direct bonded copper (DBC) substrate or an insulated metal substrate (IMS). In each case a plurality of semiconductor switching elements can be fitted on the first leadframe and the second leadframe. Advantageously, the first, the second and optionally the third leadframe are formed by the same substrate.

A cooler is arranged on the lower side of the semiconductor power module and is thermally coupled to the semiconductor switching elements in order to effectively dissipate heat which is produced during operation of the semiconductor power module owing to high power losses and in this way protect the semiconductor switching elements and further component parts of the semiconductor power module or the power converter from overheating. Preferably, the cooler is connected to the multilayered substrate, in particular to the lower metal layer of the substrate, from below. The cooler can comprise a cooling plate having a pin-fin structure arranged therebeneath and consisting of a plurality of fins which define a plurality of cooling lines through which a coolant, for example water, will flow.

In accordance with the invention, electrical contact is made with the diodes between the first leadframe and the second leadframe in such a way that the anode of the diodes faces the cooler which is mechanically connected and thermally coupled to the semiconductor power module. For example, in the case where, in the case of an individual or plurality of leadframes and associated coolers of the semiconductor power module, the anode of the diodes is arranged so as to face the leadframe, for example the first, the second or the third leadframe. This is the case when the first and/or second and/or third leadframes, as described above by way of example, is/are provided by the upper metal layer of the multilayered substrate and when the cooler is connected on the lower side to the lower metal layer of the multilayered substrate. In the diodes, for example gallium oxide-based Schottky diodes, the majority of the heat is produced in the region of the anode. By virtue of the measure according to the invention, this heat can therefore be dissipated particularly effectively, with the result that the diodes are protected better from overheating. The functionality of the entire power converter is therefore improved. In the case of such a design, it may be the case that a diode on the high side is no longer arranged on the leadframe associated with the high side but is arranged on another leadframe. Likewise, it may be the case that a diode on the low side is no longer arranged on the leadframe associated with the low side but is arranged on another leadframe. For example, the transistors on the high side are arranged on the first leadframe, and the diodes on the high side are arranged on the second leadframe. Furthermore, for example, the transistors on the low side are arranged on the second leadframe, and the diodes on the low side are arranged on the third leadframe.

In accordance with one embodiment, the semiconductor switching elements in the form of bipolar transistors, in particular in the form of insulated-gate bipolar transistors, each have a positive-pole current electrode (for example collector contact) and a negative-pole current electrode (for example emitter contact), wherein the negative-pole current electrode is arranged so as to face away from the first or second leadframe (in particular from the substrate), and the positive-pole current electrode is arranged so as to face the first or second leadframe (in particular the substrate, preferably the upper metal layer of the multilayered substrate, for example of the DBC substrate). This enables particularly simple interconnection of the bipolar transistors in order to form a half-bridge.

In accordance with a further embodiment, the semiconductor power module is in the form of a half-bridge module having a module high side and a module low side, wherein the module high side and the module low side each comprise one or more semiconductor switching elements connected in parallel. In this case, the half-bridge module itself can act as a complete half-bridge and thus provide one of a plurality of phase units of the power converter. Alternatively, a plurality of half-bridge modules can be combined with one another in order to form a half-bridge which is extended in terms of the maximum quantity of current that can be carried and therefore form an extended phase unit. The module high sides are connected in parallel with one another in order to form the high side of the combined half-bridge. At the same time, the module low sides are connected in parallel with one another in order to form the low side of the combined half-bridge. In a power converter, in particular an inverter, a plurality of, for example three, such combined half-bridges can be used, wherein each combined half-bridge forms a phase unit at whose current output one of a plurality of phase currents of the alternating current is generated.

It is furthermore proposed that the cooler encloses areally the first leadframe, the second leadframe and the third leadframe.

In addition, it is proposed that the diodes are at least partially in the form of Schottky diodes.

The invention furthermore relates to a power converter for supplying current to an electrical axle drive, in particular an electric machine installed therein and having such a semiconductor power module, a corresponding electrical axle drive and a vehicle having such an electrical axle drive. The power converter can be in the form of an inverter or a rectifier and have a plurality of (for example three) phase units. This results in the advantages already described in connection with the semiconductor power module according to the invention for the power converter according to the invention, the electrical axle drive according to the invention and the vehicle according to the invention as well.

The invention will be explained by way of example below with reference to exemplary embodiments illustrated in the figures.

### BRIEF DESCRIPTION OF THE DRAWINGS

FIG. 1 shows a schematic illustration of a semiconductor power module in plan view, wherein the semiconductor power module comprises a plurality of bipolar transistors and diodes.

FIG. 2 shows a schematic illustration of one of the diodes of the semiconductor power module from FIG. 1 in a cross-sectional view.

### DETAILED DESCRIPTION OF THE DRAWINGS

Identical objects, functional units and comparable components are denoted by the same reference signs throughout the figures. These objects, functional units and comparable components are implemented identically in terms of their technical features if not specified otherwise either explicitly or implicitly in the description.

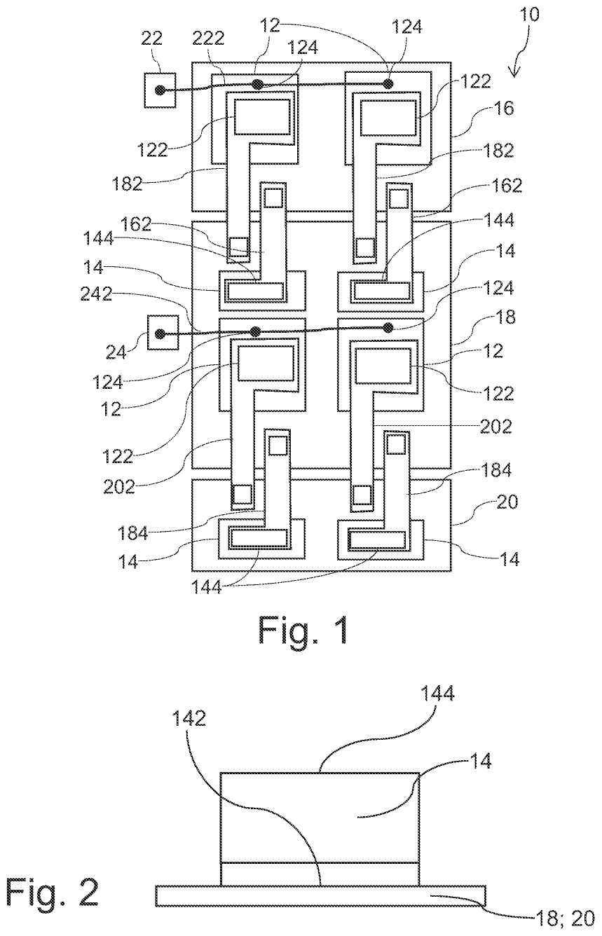

FIG. 1 shows a schematic illustration of a semiconductor power module 10 for a power converter (not shown) in a plan view. The power converter is designed to supply current to an electrical axle drive in an electric vehicle or a hybrid vehicle. The power converter is preferably in the form of an inverter for converting an input-side direct current into an output-side alternating current, further preferably a polyphase alternating current having a plurality of AC phase currents. For this purpose, the power converter or inverter has a plurality of phase units which are each interconnected so as to generate one of the AC phase currents. The semiconductor power module 10 is preferably in the form of a half-bridge module which has a module high side and a module low side and provides a complete half-bridge circuit. In the power converter, one or more such half-bridge modules can be used in combined form per phase unit. In the case where each phase unit is assigned a plurality of half-bridge modules, the module high sides of these half-bridge modules are preferably connected in parallel with one another in order to form a high-side device of the entire phase unit. At the same time, the module low sides of these half-bridge modules are preferably connected in parallel with one another in order to form a low-side device of the entire phase unit.

The semiconductor power module 10 comprises a plurality of semiconductor switching elements 12, 14, which can be switched in a targeted manner in order to bring about the current conversion. As can be seen schematically in FIG. 1, a plurality of bipolar transistors 12 and a plurality of diodes 14 are contained within the semiconductor power module 10. The bipolar transistors 12 are of the type NPN or are preferably configured as insulated-gate bipolar transistors (IGBTs or n-channel IGBTs) with silicon as the base material and the diodes 14 are preferably configured as Schottky diodes with gallium oxide as the base material. The power module 10 comprises a first leadframe 16, which in this case is, by way of example and preferably, in the form of a positive-pole DC leadframe (DC positive leadframe), a second leadframe 18, which in this case, by way of example and preferably, is in the form of an AC leadframe, and a third leadframe 20, which in this case, by way of example and preferably, is in the form of a negative-pole DC leadframe (DC negative leadframe). The first leadframe 16, the second leadframe 18 and the third leadframe 20 are formed by a single substrate, for example a DBC substrate. In addition, the power module 10 comprises a gate leadframe 22 for the module high side and a further gate leadframe 24 for the module low side. The transistors 12 are arranged with half on the positive-pole DC leadframe 16 and the other half on the AC leadframe 18. The lower contact which acts as collector electrode of the transistors 12 is physically and electrically connected to these leadframes 16, 18. The diodes 14 are arranged with half on the AC leadframe 18 and the other half on the negative-pole DC leadframe 20. An anode of the diodes 14 is physically and electrically connected to these leadframes 18, 20. The positive-pole DC leadframe 16 is electrically connected to cathode contacts 144 of the diodes 14 on the AC leadframe 18 by conductor tracks 162. The AC leadframe 18 is electrically connected to emitter contacts 122 on the bipolar transistors 12 on the positive-pole DC leadframe 16 by conductor tracks 182. The AC leadframe 18 is also electrically connected to the cathode contacts 144 of the diodes 14 on the negative-pole DC leadframe 20 by conductor tracks 184. The negative-pole DC leadframe 20 is electrically connected to the emitter contacts 122 of the bipolar transistors 12 on the AC leadframe 18 by the conductor tracks 202. The gate leadframe 22 for the module high side is electrically connected to the gate contacts 124 of the bipolar transistors 12 on the positive-pole DC leadframe 16 by the connecting wire 222. The gate leadframe 24 for the module low side is electrically connected to the gate contacts 124 of the bipolar transistors 12 on the AC leadframe 18 by the bonding wire 242.

The design of the diodes 14 is shown in FIG. 2 in a schematic cross-sectional view. The diode 14 comprises an anode 142 and a cathode 144. As can be seen in FIG. 2, the anode 142 in the built-on state of the diode 14 faces the lower AC leadframe 18 or the negative-pole DC leadframe 20. A cooler (not shown here) is preferably connected on the lower side to the lower leadframe 18 or 20 in order to dissipate heat which is produced during operation of the semiconductor switching elements 12, 14. As a result of the fact that, in the case of a diode 14, the heat is generated primarily in the region of the anode 142, such an arrangement is particularly advantageous for the purpose of effective heat dissipation.

### LIST OF REFERENCE SIGNS

10 semiconductor power module
12 bipolar transistors
122 emitter contact
124 gate contact
14 diodes
142 anode
144 cathode contact
16 first leadframe (positive-pole DC leadframe)
162 conductor tracks for positive-pole DC leadframe
18 second leadframe (AC leadframe)
182 conductor tracks for AC leadframe to the positive side
184 conductor tracks for AC leadframe to the negative side
20 third leadframe (negative-pole DC leadframe)
202 conductor tracks for negative-pole DC leadframe
22 gate leadframe for module high side
222 gate wiring for module high side
24 gate leadframe for module low side
242 gate wiring for module low side

1. A semiconductor power module for a power converter for supplying current to an electrical axle drive in an electric vehicle and/or a hybrid vehicle, comprising:
a plurality of semiconductor switching elements configured to generate an output current on a basis of an input current provided by a voltage source by switching the semiconductor switching elements, wherein the semiconductor switching elements comprise at least one diode which each have an anode and a cathode;
a first leadframe and a second leadframe having a plurality of conductor tracks configured to electrically connect the semiconductor switching elements in order to form a half-bridge having a high side and a low side on a basis of the semiconductor switching elements, wherein the first leadframe and the second leadframe are provided by regions of an upper metal layer of a multilayered substrate which are electrically insulated from one another or potentially isolated, wherein electrical contact is made with the diodes between the first leadframe and the second leadframe in such a way that the anode of the diode faces a cooler which is mechanically connected and thermally coupled to the semiconductor power module, wherein the cooler is connected to the multilayered substrate from below.

2. The semiconductor power module according to claim 1, wherein the first leadframe is assigned to the high side and the second leadframe is assigned to the low side.

3. The semiconductor power module according to claim 1, wherein the first leadframe and the second leadframe are provided by regions of an upper metal layer of a multilayered substrate which are electrically insulated from one another and potentially isolated, and wherein the cooler is connected to the multilayered substrate from below.

4. The semiconductor power module according to claim 1, wherein the first leadframe is a positive-pole DC leadframe, wherein the second leadframe is an AC leadframe, wherein the cooler is arranged on a side of the semiconductor power module which faces the second leadframe, wherein the anode of the diode is arranged so as to face the second leadframe and/or at least one further diode is arranged with its anode facing a third leadframe, which is a negative-pole DC leadframe.

5. The semiconductor power module according to claim 1, wherein the semiconductor switching elements also comprise a plurality of transistors which each have a positive-pole current electrode and a negative-pole current electrode.

6. The semiconductor power module according to claim 5, wherein the plurality of transistors comprise insulated-gate bipolar transistors.

7. The semiconductor power module according to claim 5, wherein the negative-pole current electrode is arranged so as to face away from the second leadframe.

8. The semiconductor power module according to claim 1, wherein the semiconductor switching elements, are based at least partially on a gallium oxide compound.

9. The semiconductor power module according to claim 8, wherein the diodes are based at least partially on the gallium oxide compound.

10. The semiconductor power module according to claim 1, wherein the first and/or second leadframes are provided by an upper metal layer of a multilayered substrate, which additionally comprises a lower metal layer and a layer of insulation arranged between the upper metal layer and the lower metal layer.

11. The semiconductor power module according to claim 4, wherein the first, second and/or third leadframes are provided by an upper metal layer of a multilayered substrate, which additionally comprises a lower metal layer and a layer of insulation arranged between the upper metal layer and the lower metal layer.

12. A power converter for supplying current to an electrical axle drive in an electric vehicle and/or a hybrid vehicle, comprising at least one of the semiconductor power module according to claim 1.

13. The power converter according to claim 12, comprising an inverter.

14. An electrical axle drive for an electric vehicle or a hybrid vehicle, comprising:
an electric machine;
a gear device; and
the power converter according to claim 12.

15. An electric vehicle or hybrid vehicle, comprising the electrical axle drive according to claim 14.
